(19) United States
(12) Patent Application Publication
(10) Pub. No.: US 2018/0136369 A1
(43) Pub. Date: May 17, 2018

(54) Coated Object and Method for Producing a Coated Object

(71) Applicant: Fraunhofer-Gesellschaft zur Förderung der angewandten Forschung e.V., München (DE)

(72) Inventors: Michael Vergöhl, Destedt (DE); Stefan Bruns, Cremlingen (DE); Hans-Ulrich Kricheldorf, Bad Harzburg (DE); Lothar Schäfer, Meine (DE); Markus Höfer, Cremlingen (DE); Markus Armgardt, Braunschweig (DE)

(21) Appl. No.: 15/569,079

(22) PCT Filed: Apr. 13, 2016
(86) PCT No.: PCT/EP2016/058115

§ 371 Date: Oct. 24, 2017

(30) Foreign Application Priority Data
Apr. 24, 2015 (DE) 10 2015 106 368.9

(51) Int. Cl. G02B 1/115; G02B 1/14; G02B 1/02; C23C 14/35; C23C 16/505; C23C 16/27; C23C 16/511

(52) U.S. Cl. CPC G02B 1/115; G02B 1/14; G02B 1/02; C23C 16/511; C23C 16/505; C23C 16/271; C23C 14/35

(57) ABSTRACT

A coated object and a method for producing a coated object are disclosed. In an embodiment, the coated object includes a substrate and an optical coating disposed on the substrate, wherein the optical coating includes a reflection-reducing layer sequence, which includes a covering layer with a refractive index n_{A} and at least one diamond layer with a refractive index n_{D1}>n_{A}, wherein the diamond layer is disposed between the covering layer and the substrate and includes diamond crystals, and wherein the diamond layer has a layer thickness of less than 500 nm.

This patent application is a national phase filing under section 371 of PCT/EP2016/058115, filed Apr. 13, 2016, which claims the priority of German patent application 10 2015 106 368.9, filed Apr. 24, 2015, each of which is incorporated herein by reference in its entirety.

### TECHNICAL FIELD

The invention relates to a coated object. The invention further relates to a method for producing a coated object.

### BACKGROUND

Objects with a coating, in particular, with an antireflective coating for the visible range, are widely used in industry. These coated objects are therefore subject to stringent requirements since they are, in some cases, exposed to high mechanical stresses. However, modern coatings display severe wear through hazing or abrasion after a short time in apparently relatively undemanding tests, e.g. the sand trickling test. Coatings are therefore needed which can withstand long-term abrasive stresses, under extreme conditions in some cases, and are insensitive to impacts.

### SUMMARY OF THE INVENTION

Embodiments provide a stable and reflection-reducing or reflection-reduced coated object. In various embodiments, the coated object exhibits high hardness and/or scratch resistance besides low reflection.

In at least one embodiment, the coated object comprises a substrate. An optical coating is disposed on the substrate. The optical coating contains a reflection-reducing layer sequence. The reflection-reducing layer sequence contains or comprises a covering layer with a refractive index nA and at least one diamond layer with a refractive index nD1>nA. The diamond layer is disposed between the covering layer and the substrate. The diamond layer contains diamond crystals. In particular, the diamond layer consists of diamond crystals or diamond nanocrystals. The diamond layer has a layer thickness of <500 nm.

According to at least one embodiment, the reflection-reducing layer sequence has a reflectance of less than or equal to 3%, in particular of less than 1%. Alternatively or in addition, the diamond layer has a transmission of greater than 80%, in particular greater than 90%, e.g. over 95%, at least in a wavelength range of 420 nm to 680 nm, i.e. in the visible wavelength range.

According to at least one embodiment, the reflection-reducing layer sequence has a reflectance of less than 1% in a wavelength range of 420 nm to 680 nm. In addition, the diamond layer can be disposed between the covering layer and a second layer with a refractive index n2<nD1, wherein the covering layer and the diamond layer are in direct mechanical contact and/or wherein a first layer with a refractive index n1 is disposed between the diamond layer and the covering layer, wherein nD1>n2>n1 applies.

According to at least one embodiment, the coated object comprises a substrate. The substrate can be any object that is suitable for coating. In particular, the substrate is made of glass, such as quartz glass, or sapphire. In particular, the substrate consists of a transparent material, such as glass, quartz glass or sapphire. The substrate can be an optical component. Optical components are e.g. lenses, in particular for binoculars, endoscopes or optical sensors. The substrate can also be e.g. a consumer article, e.g. a watch, smartphone, smartwatch or fingerprint sensors or displays of mobile telephones or watches. In particular, the substrate is a watch glass. The substrate can be an object from the sector of photovoltaics, solar thermal systems, e.g. solar cells, architecture and/or the automotive sector. For example, the substrate is a sun roof of a car. The substrate can be a component of various products on the market.

The substrate can be an object from the medical technology sector. For example, the substrate is the cover glass of an endoscope.

In particular, the coated object can also find new applications in which, up to now, conventional coated objects have not yet been employed. For example, the optical coating can be used for the coated object according to the invention in a harsh environment, e.g. in a desert climate, or in oil drilling systems. The coating can also be used in sectors where equipment is sterilized, which takes place under high pressure, e.g. 5 bar, and/or at a high temperature, e.g. 135° C. These pressures or temperatures can be present during steam sterilization in an autoclave.

The inventors have found that, by using an optical coating on a coated object according to the invention, an object or a product can be provided which is insensitive to abrasive stresses, wear, abrasion, impacts, scratches and/or environmental effects, such as corrosion. In addition, the optical coating has anti-reflective characteristics, i.e. in particular a reflection of less than 1% in the visible range. In particular, the inventive object according to claim 1 exhibits extreme scratch resistance compared to other existing technical solutions.

Up to now, reflection-reducing optical coatings for the visible range have been known which do not exhibit adequate hardness. For example, these coatings exhibit a maximum hardness of the material of approximately 10 GPa. The inventors have now found that, by using an optical coating in a coated object according to claim 1, a coated object can be provided which is very hard and has layer hardnesses of 60 to 100 GPa. A super-hard antireflective coating on an object can therefore be provided.

According to at least one embodiment, the coated object has an optical coating. The optical coating has a layer sequence, in particular a reflection-reducing layer sequence. The term “reflection-reducing” here and below means that the layer sequence has a reflection or a reflectance of less than or equal to 3%, in particular less than 1%, in the visible range, i.e. at least in a wavelength range of 420 nm to 680 nm. The layer sequence comprises a covering layer. The term “covering layer” here and below means the layer of the layer sequence which is furthest away from the substrate. In other words, the covering layer is the outermost layer of the optical coating. The covering layer has a refractive index nA.

According to at least one embodiment, the covering layer contains a material which is selected from a group comprising aluminum oxide, silicon dioxide, aluminum nitride, silicon nitride, crystalline aluminum oxide and a mixture of Al2O3 and SiO2 Si3N4 or AlN.

According to at least one embodiment, the covering layer is formed using crystalline aluminum oxide and/or has a layer hardness of >15 GPa, in particular >20 GPa, e.g. 25 GPa or 30 GPa. The hardness can be determined by nanoindentation or a nanoindenter. Alternatively or in addition, the diamond layer has a layer hardness of >60 GPa.

The hardness alone is not the only decisive factor in the suitability of the layer in an optical coating. In addition to the established nanoindentation test, therefore, practical tests, e.g. TABER ABRASER and/or the sand trickling test, can also be used to determine hardness. To supplement these, further investigations can also be carried out, e.g. into autoclavability.

The crystalline aluminum oxide can be e.g. an alpha-aluminum oxide (corundum). Alpha-aluminum oxide has a refractive index of 1.77 at a wavelength of 550 nm. Alpha-aluminum oxide is very hard and has a hardness of 20 to 35 GPa. Alternatively or in addition, instead of alpha-aluminum oxide, gamma- or beta-aluminum oxide can also be used.

Aluminum oxide can only be obtained in crystalline aluminum oxide phases by high ion bombardment and at high temperatures. This is true in particular for the alpha-aluminum oxide phase (sapphire). Alpha-aluminum oxide is formed thermodynamically only from 1000° C. For the aluminum oxide layer to crystallize, the ion bombardment must be as high as possible. It is therefore possible to work in particular with a bias on the substrate and with highly ionized plasmas (HiPIMS). The biases must be high-frequency, particularly for insulating substrates. Depending on the substrate thickness, average frequencies range up to approx. 300 kHz. Alternatively, a radio-frequency bias voltage can be used.

According to at least one embodiment, the covering layer has a refractive index nA of no more than 1.76. As a result, a reflection of less than or equal to 1% can be achieved.

According to at least one embodiment, the covering layer contains a mixture of aluminum oxide and silicon dioxide, i.e. a crystalline Al2O3-SiO2 mixed layer, in particular a crystalline α-Al2O3-SiO2 mixed layer. Thus, the refractive index of the covering layer can be adjusted individually depending on the mixing ratio between the refractive index of aluminum oxide (1.7) and silicon dioxide (1.5). By incorporating silicon dioxide, however, crystallization is made more difficult and the hardness is reduced. In particular, the mixed layer composed of aluminum oxide and silicon dioxide has the empirical formula a SiO2·b Al2O3. The mixing ratios a:b and layer thicknesses are given in EP 2628818 A1. The disclosure content of this application is hereby incorporated by reference.

According to at least one embodiment, the covering layer has a layer thickness of 10 nm to 300 nm, in particular 50 nm to 150 nm, particularly preferably 60 nm to 90 nm. In particular, individual layer thicknesses depend especially on the stack design or layer sequence used.

According to at least one embodiment, the coated object comprises at least one diamond layer. The diamond layer has a refractive index nD1. The refractive index is in particular greater than the refractive index nA of the covering layer. The diamond layer is disposed between the covering layer and the substrate.

A layer being disposed between two other layers can mean here and below that the one layer is disposed immediately in direct mechanical contact or in indirect contact with one of the other two layers and in direct mechanical contact or in indirect contact with the other of the other two layers. In the case of indirect contact here, further layers can then be disposed between the one and at least one of the other two layers.

The diamond layer can comprise diamond crystals. In particular, the diamond crystals have a polycrystalline and/or nanocrystalline layer construction. In particular, the diamond layer consists of diamond crystals.

The diamond layer is obtainable by means of chemical vapor deposition (CVD). In particular, the diamond layer is produced by means of HFCVD (hot-filament CVD, hot-filament vapor deposition). In HFCVD or in other production methods for diamond, high temperatures and extreme conditions prevail since atomic hydrogen is present.

According to at least one embodiment, the vapor deposition is plasma-enhanced CVD.

Here, a gaseous hydrocarbon, such as methane, can be fed into a reaction chamber in hydrogen, wherein the process gases hydrogen and a gaseous hydrocarbon, usually methane, and optionally also additions of oxygen, are decomposed on a hot filament composed of e.g. tungsten, molybdenum or tantalum at a temperature of 800 to 2500° C., e.g. 2000 to 2500° C. The decomposed process gas leads to the deposition of diamond on the substrate.

Alternatively, production of diamond layers by means of plasma-enhanced CVD is also possible. Here, radio-frequency waves, but preferably microwaves, can be used. The free radicals here are produced not catalytically by hot filaments, as in HFCVD, but by plasma.

To avoid optical scattering in the at least one diamond layer, the dimensions of the resulting crystal structures must be significantly below the wavelength of visible light. This requires a highly defect-free poly- and/or nanocrystalline layer which is as finely crystalline as possible. Compared to a diamond layer with coarsely crystalline layers, the at least one diamond layer has a higher grain boundary density. This reduces the hardness of the diamond layer and can lead to losses of absorption. A precondition for the production of the at least one diamond layer is the achievement of very high and uniform grain densities of >1012 cm-2 in a pretreatment step adapted to the preceding coatings.

The layers of the layer sequence that are produced before the application of the at least one diamond layer have to be especially stable towards the high temperatures of e.g. 600 to 900° C. that prevail in the hot-filament vapor deposition process. Alternatively, it is also possible to operate in a process with lower substrate temperatures of up to 500° C. Furthermore, the layers of the layer sequence also have to be stable towards the action of atomic hydrogen. Hydrogen radicals can chemically reduce preceding oxide layers, e.g. first layers and/or second layers, which could lead to substoichiometric boundary layers with modified optical properties. In particular, the layers of the layer sequence deposited before the at least one diamond layer are compatible with and/or stable towards high temperatures of at least between 500 and 900° C., in particular between 600° C. and 900° C.

In particular, the diamond layer exhibits low scattering, high transmission and/or good stoichiometry, particularly since a low influence of the seed layer is present. In particular, the seed layer is formed very thinly.

According to at least one embodiment, the diamond layer has a layer thickness of <500 nm. In particular, the diamond layer has a layer thickness of 50 to 200 nm, in particular 60 to 150 nm, e.g. 130 nm.

The diamond layer, which is produced in particular by hot-filament vapor deposition, exhibits high optical transparency. The term “transparent” here and below refers to a layer that transmits visible light. In this case, the transparent layer can be clearly translucent or at least partially light scattering and/or partially light absorbing, so that the transparent layer can also be e.g. diffusely or milkily translucent. Particularly preferably, the layer referred to here as transparent transmits as much light as possible, so that in particular the absorption and also the scattering of visible light are as low as possible.

According to at least one embodiment, the diamond layer is formed homogeneously and/or uniformly. This means here and below that the diamond layer has an almost even layer thickness, e.g. a uniform layer thickness, with a tolerance of less than or equal to 10%, 5% or 1%. This homogeneous layer thickness can be produced in particular by means of hot-filament vapor deposition. In particular, with respect to the uniformity of the layer, specifications must be met which are far more stringent than those of other fields of technology in which diamond layers are also employed. The extraordinarily high uniformity of thickness is achieved by special adaptations of the coating process, e.g. in the HFCVD process by extremely precise control of the distance of the activating filaments from the substrate surface and the arrangement of the filaments in relation to one another in order to achieve the most even activation of the vapor phase possible. A further measure for obtaining particularly homogeneous layer thicknesses can be the translational or rotational motion of the substrate during coating, by which remaining residual uniformities are averaged out. Compared with other methods that are suitable for diamond coating, the HFCVD method in particular offers especially good conditions because no (high-frequency) electrical fields are required on or close to the substrate here. To achieve particularly uniform diamond deposition, especially at the edges of the substrates to be coated, special surrounds and masks can be employed with which elevated edges are reduced. A further tried and tested measure for controlling the layer thickness distribution can be the targeted flow of the processes gases on to the substrate surfaces.

According to at least one embodiment, the layer sequence has at least four layers, in particular at least five or six or seven layers. One or more of these layers can be diamond layers. Alternatively or in addition, the layer sequence has no more than twelve layers, e.g. a total of five or seven layers. In principle, there is no upward limit to the number of layers. In particular, at least one diamond layer and a covering layer are part of the layer sequence. For economic reasons, the optical coating should not exceed a layer count of twelve. In particular, the diamond layer has a layer thickness of less than or equal to 300 nm.

The layer sequence is a composite, and so the complete stack is to be studied. The production of the diamond layer is the most complex here. It is therefore advantageous to use only one diamond layer within the layer sequence where possible. Apart from this practical reason, however, the method can also be applied to a layer stack having more than one diamond layer.

According to at least one embodiment, the diamond layer is disposed between the covering layer and a second layer with a refractive index n2<nD1. In particular, the covering layer and the diamond layer are in direct mechanical contact with one another. Alternatively, a first layer with a refractive index n1 is disposed between the diamond layer and the covering layer. The following applies here: nD1>n2>n1. The term “disposed directly” here and below means that the one layer is disposed immediately on the other layer in direct mechanical contact therewith.

In other words, in particular a coated object is provided here containing a diamond layer at least as the second or third layer from the top of the optical coating. The covering layer in this case forms the uppermost layer of the optical coating. By incorporating a diamond layer into an optical coating, in particular for the visible range of the spectrum (420 to 680 nm), a hard and stable optical coating can be provided because diamond has a hardness of >60 GPa which cannot be surpassed by any other material.

In addition, the covering layer can be formed using crystalline aluminum oxide with a hardness of >20 GPa. Thus, an optical coating can be provided for an object, which provides a super-hard broadband antireflective coating for any applications. In particular, the combination of crystalline diamond with crystalline aluminum oxide (sapphire) gives an optical coating having a high layer hardness, particularly with the correct adjustment of the layer thicknesses, and a high antireflective function.

According to at least one embodiment, the diamond layer has a refractive index of 2.4 at 550 nm. By means of the combination of the materials of diamond and aluminum oxide, particularly using further subjacent layers which are needed for the optical system, a new super-hard antireflective coating for an object can be obtained which far outperforms previously known coatings in terms of stability.

In addition, a robust optical coating for any applications can be provided.

According to at least one embodiment, the second layer comprises a material selected from the group comprising TiO2 (refractive index 2.45-2.65), Nb2O5 (refractive index 2.3), Al2O3 (refractive index 1.60-1.77), Si3N4 (refractive index 1.9 to 2.1), HfO2 (refractive index 2.08) and ZrO2 (refractive index 2.15). In particular, the refractive indices quoted in brackets are valid for 550 nm.

In particular, Al2O3 is used for the second layer since, while titanium dioxide has a high refractive index of 2.45, it is, however, very soft. Niobium oxide has a refractive index of 2.3 but is softer than titanium dioxide.

Through the use of a diamond layer with a high refractive index and high hardness, the overall layer sequence can be stabilized and supported. Thus, the covering layer is also stabilized and supported, and so the optical coating has higher overall stability. Thus, the optical coating is in particular very highly insensitive to scratches.

According to at least one embodiment, the first layer comprises or consists of silicon dioxide. Silicon dioxide has a refractive index of 1.45.

According to at least one embodiment, the layer sequence additionally contains one or more pairs of layers. The pairs of layers are disposed directly after the substrate, i.e. in direct mechanical contact therewith. The pairs of layers each have at least one first layer, in particular a first layer with a refractive index n1, and at least one second layer, in particular a second layer with a refractive index n2>n1. The diamond layer is disposed between the first and second layers of a pair of layers. Alternatively or in addition, the diamond layer is disposed directly after one or more pairs of layers, i.e. in direct mechanical contact therewith. Over the diamond layer, the covering layer is disposed. The term “over” here and below means that one layer is disposed directly on the other layer in direct mechanical and/or electrical contact therewith. Furthermore, it can also mean that the one layer is disposed indirectly over the other layer. In this case, further layers can then be disposed between one layer and the other. In particular, the covering layer and the diamond layer are disposed in direct mechanical contact with one another. In particular, the following can apply: nD1>n2>n1 and n1≤nA≤n2 and nD1>n2+x*0.6 with 0.1≤x≤1. In particular, the following can apply for x: 0.7≤x≤1. Alternatively the following can apply: nD1≤n2>n1 and n1≤n2≤n2.

According to at least one embodiment, the layer sequence is capable of transmitting radiation with a dominant wavelength λ. The following applies here: for the thickness of the diamond layer 0.1 λ/4≤nD1*dD1≤1.3 λ/4 and/or for the thickness of the covering layer 0.1 λ/4≤nA*dA≤1.3 λ/4 and/or for the thickness of the first layer 0.1 λ/4≤n1*d1≤1.3 λ/4 and/or for the thickness of the second layer 0.1 λ/4≤n2*d2≤1.3 λ/4. In particular, the following applies: for the thickness of the diamond layer 0.3 λ/4≤nD1*dD1≤0.8 λ/4 and/or for the thickness of the covering layer 0.7 λ/4≤nA*dA≤1.3 λ/4 and/or for the thickness of the first layer 0.7 λ/4≤n1*d1≤1.3 λ/4 and/or for the thickness of the second layer 0.7 λ/4≤n2*d2≤1.3 λ/4.

According to at least one embodiment, the layer sequence comprises at least one additional diamond layer, referred to below as the second diamond layer, with a refractive index nD2. The second diamond layer is disposed between the covering layer and the substrate. In particular, the second diamond layer is disposed between the first diamond layer and the substrate. The two diamond layers are each separated from one another by a first layer with a refractive index n1 and/or by a second layer with a refractive index n2. The covering layer is disposed in particular directly after one of the diamond layers, in particular the first diamond layer. The following applies here: nD1>n1+0.4 and/or nD2>n1+0.4 and/or n1>n2+0.2 and/or nD2>n2+0.2 and/or nD1=nD2. In particular, the following applies: nD1>n1+0.8 and/or nD2>n1+0.8 and/or n1>n2+0.4 and/or nD2>n2+0.4 and/or nD1=nD2.

In particular, the first layer can be formed using silicon dioxide and/or the second layer can be formed using aluminum oxide. Thus, a coated object can be provided, having a hard and scratch-resistant optical coating which is stable towards environmental effects.

The invention further relates to a method for producing a coated object. The same statements and definitions as described above for the object also apply to the method and vice versa. According to at least one embodiment, the method comprises the following method steps: A) providing a substrate and B) applying a reflection-reducing layer sequence, wherein the at least one diamond layer is produced by means of vapor deposition, in particular chemical vapor deposition, e.g. hot-filament vapor deposition or microwave CVD, and then the covering layer is produced by means of magnetron sputtering.

The pretreatment and vapor deposition, in particular hot-filament vapor deposition, should be designed such that a diamond layer is grown which is as even and absorption-free as possible and a stable interface is obtained between the diamond layer and the adjacent layers or the substrate. The absorption-free nature of the diamond layer can be achieved by using low concentrations of the hydrocarbon, in particular at concentrations of greater than or equal to 1% methane diluted in up to 99% hydrogen, and/or activation of the vapor phase by high filament temperatures in the HFCVD method and/or high power densities, for example in microwave-activated CVD.

According to at least one embodiment, the diamond layer is directly followed by a silicon nitride layer. The silicon nitride layer has in particular a layer thickness of a few nanometers or several 10 nm to a few 100 nm, for example between 20 nm and 300 nm. As a result, the diamond surface can be protected by the subsequent coatings from ion bombardment, e.g. by means of magnetron sputtering, and the adhesion of the diamond layer to adjacent oxide layers can be improved. The silicon nitride layer can be produced in particular by hot-filament vapor deposition and/or magnetron sputtering.

Alternatively, the diamond layer can be disposed directly after a silicon nitride layer in order to improve the adhesion of the diamond layer and/or to prevent oxide layers from being reduced by atomic hydrogen.

The term “magnetron sputtering” means in particular pulsed reactive magnetron sputtering. In particular, magnetron sputtering includes High Power Impulse Magnetron Sputtering (HiPIMS). In particular, oxide-containing and/or nitride-containing layers are produced by means of magnetron sputtering.

Furthermore, vapor deposition, in particular hot-filament vapor deposition, is used here for applying the at least one diamond layer. Through the use of hot-filament vapor deposition, diamond layers with a uniform layer thickness can be produced. In particular, diamond layers can be produced on areas of 500×1000 mm2. In particular, the diamond layers are thin and free from defects. This can be achieved in particular by carrying out high-power seeding procedures.

According to at least one embodiment, the vapor deposition, in particular hot-filament vapor deposition, and the magnetron sputtering take place in one apparatus. This can enable both the application of oxide and/or nitride layers by means of magnetron sputtering and the deposition of at least one diamond layer to take place in one apparatus. This saves costs, material, time and space. Moreover, a loss of vacuum between the individual coatings can be avoided, potentially improving the adhesion between the individual layers. In addition, a coating line that combines the two deposition methods can offer the possibility of producing layer systems with more than one diamond layer economically. By combining hot-filament vapor deposition for diamond layers with magnetron sputtering for oxide and/or nitride layers, it is ensured that a coated object is provided which has a stable, scratch-resistant, hard optical coating. Alternatively, instead of magnetron sputtering, electron beam vapor deposition can also take place and instead of hot-filament vapor deposition, other methods of diamond deposition can also be employed, e.g. microwave-activated vapor deposition.

In particular, a coated object with an optical coating is provided, which coating comprises in particular a dielectric layer sequence with at least one diamond layer. The diamond layer can occupy the position of a highly refractive layer. The diamond layer can be applied on a sputtered oxide layer and an oxide layer can in turn be applied on the diamond layer.

Compared with previously known coatings, e.g. composed of silicon dioxide and titanium dioxide, optical coatings for an object according to the invention exhibit high hardness, scratch resistance, high stability even towards environmental effects and also very low residual reflection.

Advantages, advantageous embodiments and developments can be taken from the exemplary embodiments described below in association with the figures.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a schematic diagram of a coated object according to one embodiment;

FIG. 2 shows a schematic diagram of a coated object according to one embodiment;

FIG. 3 shows the reflectance in per cent as a function of the wavelength λ in nm of a comparative example and of two exemplary embodiments; and

FIG. 4 shows a schematic diagram of a coated object according to one embodiment.

### DETAILED DESCRIPTION OF ILLUSTRATIVE EMBODIMENTS

In the exemplary embodiments and figures, identical or similar elements or elements having the same effect can be provided with the same reference numbers. The elements illustrated and the size ratios to one another thereof should not be considered as being to scale. Rather, to illustrate them better and/or to make them easier to understand, the size of individual elements, such as e.g. layers, may be exaggerated. In particular, the layers or the layer thicknesses illustrated are not to scale.

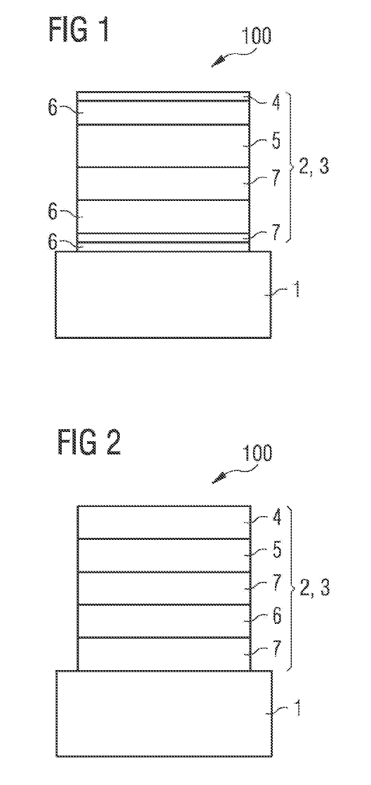

FIG. 1 shows a schematic side view of a coated object 100. The coated object 100 contains a substrate 1. The substrate 1 can be composed of e.g. glass or sapphire. On the substrate, a first layer 6 with a refractive index n1 is then disposed. The first layer 6 can comprise or consist of e.g. silicon oxide or silicon dioxide. The first layer 6 is followed by a second layer 7 with a refractive index n2. The second layer 7 can consist of e.g. aluminum oxide or can comprise aluminum oxide. The second layer 7 is followed by a further first layer 6, which can in turn comprise in particular silicon oxide or silicon dioxide. This further first layer 6 is in turn followed by a further second layer 7, which can comprise e.g. aluminum oxide. The coated object 100 thus comprises as optical coating 2 a reflection-reducing layer sequence 3 having two pairs of layers, which are disposed after the substrate 1 and each comprise a first layer 6 and a second layer 7. These two pairs of layers are followed directly by a diamond layer 5, i.e. they are in direct mechanical contact therewith. In particular, the diamond layer 5 has a layer thickness of 50 nm to 150 nm, e.g. 130 nm. The diamond layer 5 is directly followed by a further first layer 6, which contains e.g. silicon oxide or silicon dioxide. This further first layer 6 is followed by the covering layer 4 as the uppermost layer. The covering layer 4 can contain e.g. crystalline aluminum oxide or a mixture of aluminum oxide and silicon dioxide to reduce the refractive index. The coated object 100 according to FIG. 1 thus contains a layer sequence 3 consisting of seven layers. The layer sequence 3 can in particular have a layer thickness of 540 nm in total. Thus, a coated object 100 can be provided having a scratch-resistant, hard, antireflective coating 2 for at least the visible range of the spectrum.

FIG. 2 shows a coated object 100 according to one embodiment. The coated object 100 contains a substrate 1. The substrate 1 is followed by a layer sequence 3 of an optical coating 2. The layer sequence 3 comprises two second layers 7 each with a refractive index of n2. One of the two second layers 7 is disposed directly on the substrate 1. The second layer 7 is followed by a first layer 6 with a refractive index n1. The first layer 6 is followed by a further second layer 7. The further second layer 7 is followed by a diamond layer 5. The diamond layer 5 is followed by a covering layer 4. The covering layer 4 is the outermost layer of the optical coating 2. Thus, the diamond layer 5 is the penultimate layer 5 of the optical coating 2, directly below the covering layer 4. The coated object 100 according to FIG. 2 thus contains a layer sequence 3 consisting of five layers. The total thickness of the optical coating 2 can be approximately 540 nm. The covering layer 4 contains in particular crystalline aluminum oxide and silicon dioxide. Silicon dioxide is added particularly in order to reduce the refractive index of aluminum oxide (1.7).

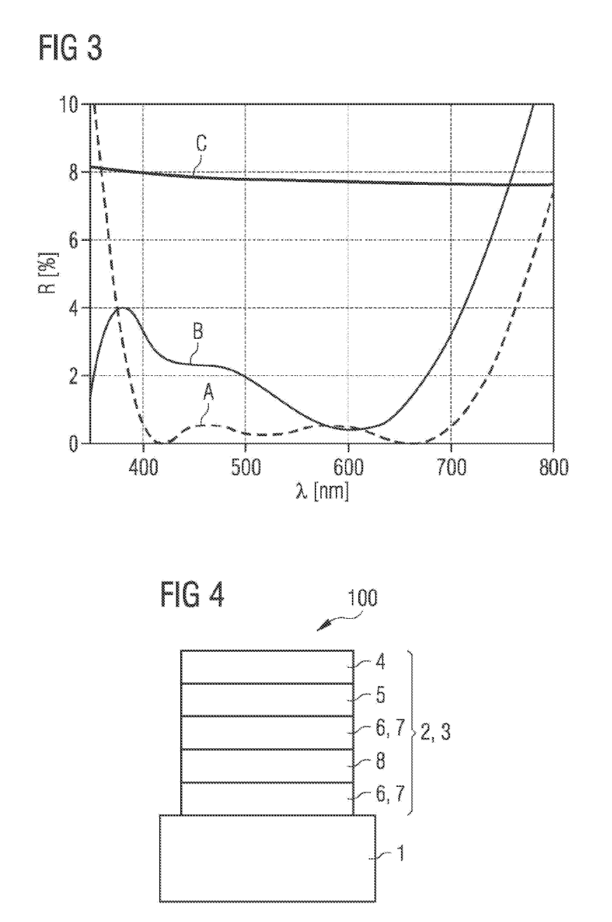

FIG. 3 shows a graphic representation of the reflection or reflectance R in per cent (%) as a function of the wavelength in nanometers (nm).

Graph A shows the reflectance in per cent of the exemplary embodiment of FIG. 1. In particular, the coated object 100 according to FIG. 1 has a reflectance R of <1%, in particular less than 0.8%, in the visible range, i.e. between 420 nm and 680 nm.

Graph B shows the reflectance or reflection in per cent of the exemplary embodiment of FIG. 2. The coated object 100 according to FIG. 2 shows a reflectance R of between 1.8% and 3% in the visible range of the spectrum between 420 and 520 nm. Between 520 nm and 580 nm, R is between 0.8% and 1.8%. In the wavelength range of 580 to 640 nm, the exemplary embodiment of FIG. 2 has a reflectance R of less than 1%. Between 640 and 68 nm, the reflectance is less than 2%.

FIG. C shows the reflectance in per cent of sapphire in a wavelength range of 360 nm to 800 nm. Sapphire shows a reflectance of about 8%. All the reflection values relate to one side, i.e. without taking account of rear side reflection. Reflection or reflectance refers here and below to the ratio between reflected and incident intensity.

FIG. 4 shows a schematic diagram of a coated object 100 according to one embodiment. The coated object 100 displays a substrate 1. On the substrate 1, an optical coating 2 with a reflection-reducing layer sequence 3 is disposed. The layer sequence 3 contains two diamond layers 5, 8. The first diamond layer 5 is disposed directly below the covering layer 4. The two diamond layers 5, 8 are each separated from one another by a first layer with a refractive index n1 and/or a second layer with a refractive index n2 6, 7. The following applies in particular here: nD1>n1+0.8 and nD2>n1+0.8 and/or nD1>n2+0.4 and nD2>n2+0.4 and/or nD1=nD2.

In particular, the first layer 6 is formed using silicon dioxide. In particular, the second layer 7 is formed using aluminum oxide. The covering layer 4 is in particular formed using crystalline aluminum oxide. Alternatively, it is also possible to introduce more than two diamond layers 5, 8 in a coated object 100. For example, three, four, five or six diamond layers can be introduced in a coated object. In particular, the production of the diamond layer by means of hot-filament vapor deposition is particularly complex here. It is therefore preferable to introduce as few diamond layers as possible into a coated object 100.

The exemplary embodiments described in association with the figures and the features thereof can also be combined with one another according to further exemplary embodiments, even if these combinations are not shown explicitly in the figures. Furthermore, the exemplary embodiments described in association with the figures can have additional or alternative features according to the description in the general part.

The description with the aid of the exemplary embodiments does not limit the invention thereto. Rather, the invention comprises any new feature and any combination of features, which in particular includes any combination of features in the patent claims, even if this feature or this combination is not itself explicitly stated in the patent claims or exemplary embodiments.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1-11. (canceled)

12. A coated object comprising:
a substrate; and
an optical coating disposed on the substrate, wherein the optical coating comprises a reflection-reducing layer sequence, which comprises a covering layer with a refractive index n_{A} and at least one diamond layer with a refractive index n_{D1}>n_{A}, wherein the diamond layer is disposed between the covering layer and the substrate and comprises diamond crystals, and wherein the diamond layer has a layer thickness of less than 500 nm.

13. The coated object according to claim 12,
wherein the reflection-reducing layer sequence has a reflectance of less than 1% in a wavelength range of 420 nm to 680 nm,
wherein the diamond layer is disposed between the covering layer and a second layer with a refractive index n₂<n_{D1},
wherein the covering layer and the diamond layer are in direct mechanical contact and/or wherein between the diamond layer and the covering layer a first layer with a refractive index n₁ is disposed, and
wherein the following applies: n_{D1}>n₂>n₁.

14. The coated object according to claim 12,
wherein the layer sequence further comprises one or more pairs of layers, which are disposed directly after the substrate, wherein each of the one or more pairs of layers comprises a first layer with a refractive index n₁ and a second layer with a refractive index n₂>n₁,
wherein the diamond layer is disposed between a first layer and a second layer of a pair of layers, and
wherein the following applies: n_{D1}>n₂>n₁ and n₁≤n_{A}≤n₂ and n_{D1}>n₂+x*0.6 with 0.1≤x≤1.

15. The coated object according to claim 12,
wherein the layer sequence further comprises one or more pairs of layers, which are disposed directly after the substrate, wherein each of the one or more pairs of layers comprises a first layer with a refractive index n₁ and a second layer with a refractive index n₂>n₁,
wherein the diamond layer is disposed between a first layer and a second layer of a pair of layers, and
wherein the following applies: n_{D1}≤n₂>n₁ and n₁≤n_{A}≤n₂.

16. The coated object according to claim 12,
wherein the layer sequence further comprises one or more pairs of layers, which are disposed directly after the substrate, wherein each of the one or more pairs of layers comprises a first layer with a refractive index n₁ and a second layer with a refractive index n₂>n₁,
wherein the diamond layer is disposed directly after the one or more pairs of layers, wherein over the diamond layer the covering layer is disposed, and
wherein the following applies: n_{D1}>n₂>n₁ and n₁≤n_{A}≤n₂ and n_{D1}>n₂+x*0.6 with 0.1≤x≤1.

17. The coated object according to claim 12,
wherein the layer sequence further comprises one or more pairs of layers, which are disposed directly after the substrate, wherein each of the one or more pairs of layers comprises a first layer with a refractive index n₁ and a second layer with a refractive index n₂>n₁,
wherein the diamond layer is disposed directly after the one or more pairs of layers, wherein over the diamond layer the covering layer is disposed, and
wherein the following applies: n_{D1}≤n₂>n₁ and n₁≤n_{A}≤n₂.

18. The coated object according to claim 12,
wherein the layer sequence has at least five layers and/or no more than twelve layers, and
wherein the diamond layer has a homogeneous layer thickness with a layer thickness of less than or equal to 300 nm.

19. The coated object according to claim 12,
wherein the covering layer is formed using crystalline aluminum oxide and has a layer hardness, measured with a nanoindenter, of greater than 20 GPa and/or the diamond layer has a layer hardness of greater than 60 GPa.

20. The coated object according to claim 12,
wherein the covering layer comprises aluminum oxide, silicon dioxide, aluminum nitride, silicon nitride, crystalline aluminum oxide and a mixture of Al₂O₃ and SiO₂, Si₃N₄ or AlN.

21. The coated object according to claim 12,
wherein the layer sequence is capable of transmitting radiation with a dominant wavelength λ, and wherein
for a thickness of the diamond layer, 0.3 λ/4≤n_{D1}*d_{D1}≤0.8 λ/4 applies,
for a thickness of the covering layer, 0.7 λ/4≤n_{A}*d_{A}≤1.3 λ/4 applies,
for a thickness of a first layer, 0.7 λ/4≤n₁*d₁≤1.3 λ/4 applies, and
for a thickness of a second layer, 0.7 λ/4≤n₂*d₂≤1.3 λ/4 applies.

22. The coated object according to claim 12,
wherein the layer sequence further comprises at least one additional diamond layer with a refractive index n_{D2}, which is disposed between covering layer and substrate,
wherein the at least two diamond layers of the layer sequence are each separated from one another by a first layer with a refractive index n₁ and/or a second layer with a refractive index n₂,
wherein the covering layer is disposed directly after one of the diamond layers, and
wherein the following applies: n_{D1}>n₁+0.8 and n_{D2}>n₁+0.8 and/or n_{D1}>n₂+0.4 and n_{D2}>n₂+0.4 and/or n_{D1}=n_{D2}.

23. A method for producing a coated object according to claim 12, the method comprising:
providing the substrate, and
applying the reflection-reducing layer sequence,
wherein the at least one diamond layer is produced by a vapor deposition, and
wherein, afterwards, the covering layer is produced by magnetron sputtering.

24. The method according to claim 23, wherein the vapor deposition and the magnetron sputtering are carried out in one apparatus.

25. The method according to claim 23, wherein the vapor deposition is plasma-enhanced CVD.
